(19) United States
(12) Patent Application Publication
(10) Pub. No.: US 2018/0074105 A1
(43) Pub. Date: Mar. 15, 2018

(54) SUBMERSIBLE METER FOR DETECTION OF CURRENT SIGNALS

(71) Applicant: The Swain Meter Company, Mt. Pleasant, MI (US)

(72) Inventors: Brian Albert Horanoff, Blanchard, MI (US); Kirk Lee Gillespie, Clare, MI (US)

(21) Appl. No.: 15/700,891

(22) Filed: Sep. 11, 2017

Related U.S. Application Data
(60) Provisional application No. 62/394,486, filed on Sep. 14, 2016.

(51) Int. Cl. G01R 31/02; G01R 1/067; B63G 8/00

(52) U.S. Cl. CPC G01R 31/021; G01R 1/06705; B63B 2211/02; B63G 2008/007; B63G 8/001

(57) ABSTRACT

A current detection sensor is disclosed. The current detection sensor comprises a current probe configured to connect to a remotely operated vehicle (ROV). The current probe comprises a low reluctance core configured to selectively enclose about a conductor in response to an actuation of the ROV. A gauge comprising a gauge control circuit is in conductive communication with an input and an output of the current probe. The gauge controller is configured to identify transmission data for the conductor based on a detection routine. The detection routine comprises supplying an input signal to the input and monitoring a voltage at the output. Based on the voltage, the routine identifies electrical properties of the current transmitted through the conductor.

### CROSS-REFERENCE TO RELATED APPLICATION

This application claims priority to and the benefit under 35 U.S.C. § 119(e) of U.S. Provisional Patent Application No. 62/394,486, filed on Sep. 14, 2016, entitled “SUBMERSIBLE METER FOR DETECTION OF CURRENT SIGNALS,” the entire disclosure of which is hereby incorporated herein by reference.

### TECHNOLOGICAL FIELD

The disclosure relates to current measuring devices and more particularly to submersible current measuring devices.

### BACKGROUND

The disclosure relates to current or electrical meters that may be utilized to detect and quantify electrical current passing through conductors. In some applications, it may be beneficial for such meters to be utilized in remote environments where human operators may not easily travel. Accordingly, the disclosure provides for various embodiments of meters or gauges that may be configured to operate remote of a human operator.

### SUMMARY

In one aspect, the disclosure provides for a current detection sensor. The current detection sensor comprises a current probe configured to connect to a remotely operated vehicle (ROV). The current probe comprises a low reluctance core configured to selectively enclose about a conductor in response to an actuation of the ROV. A gauge comprising a gauge control circuit is in conductive communication with an input and an output of the current probe. The gauge controller is configured to identify transmission data for the conductor based on a detection routine. The detection routine comprises supplying an input signal to the input and monitoring a voltage at the output. Based on the voltage, the routine identifies electrical properties of the current transmitted through the conductor.

In another aspect, the disclosure provides for a method for detecting a performance of a cathodic rust prevention system with a current detection sensor. The method comprises connecting a current probe to a remotely operated vehicle (ROV) and maneuvering the ROV. The method further comprises controlling the ROV thereby connecting the current probe around a conductive wire and communicating a control instruction to an ROV controller of the ROV. In response to the control instruction, the method further comprises activating with the ROV controller a current detection routine of the probe. The current detection routine comprises detecting electrical properties of current transmitted through the conductive wire with the current probe.

In yet another aspect, the disclosure provides for a current detection sensor for underwater use. The current detection sensor comprises a current probe comprising a low reluctance core forming a plurality of clamp arms configured to selectively enclose about a conductor. The current detection sensor further comprises a gauge enclosed in a watertight housing. A battery is housed within the watertight housing. The gauge controller is in conductive communication with an input and an output of the current probe. The gauge controller is configured to identify current transmission data for current communicated through the conductor with a detection routine. The gauge controller is configured to control the detection routine of the current probe comprising supplying an input signal to the input of the current probe and monitoring a voltage at the output. The detection routine further comprises identifying electrical properties of current transmitted through the conductor based on the voltage.

### BRIEF DESCRIPTION OF THE DRAWINGS

FIG. 1 is an environmental view of an exemplary embodiment of a current detection sensor;

FIG. 2 is a detailed environmental view of a current detection sensor in connection with a remotely operated vehicle;

FIG. 3 is a schematic diagram of a current probe for a current detection sensor;

FIG. 4 is a block diagram of a current detection sensor; and

FIG. 5 is an exemplary embodiment of a current detection sensor in accordance with the disclosure.

### DETAILED DESCRIPTION OF EMBODIMENTS

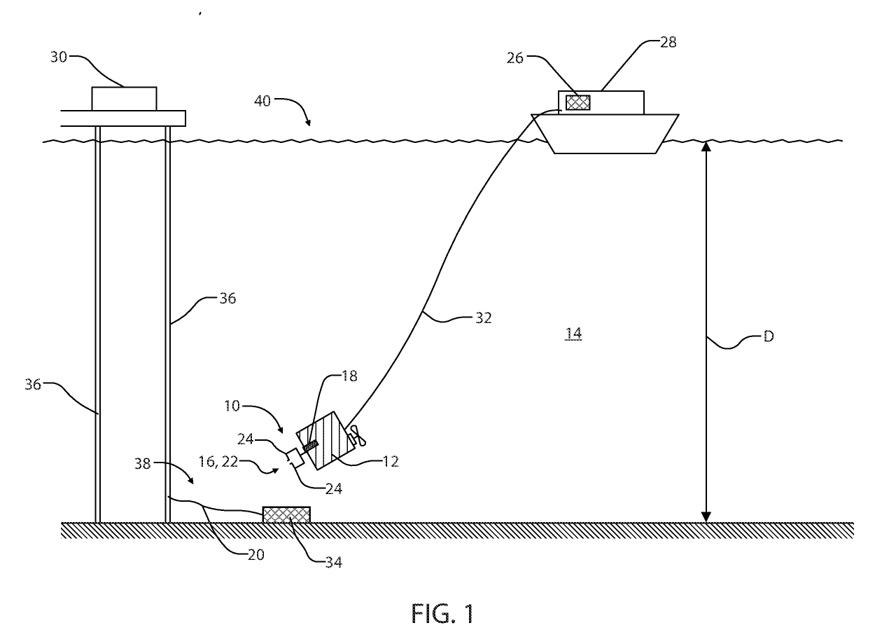

For purposes of description herein, the terms “upper,” “lower,” “right,” “left,” “rear,” “front,” “vertical,” “horizontal,” “interior,” “exterior,” and derivatives thereof shall relate to the device as oriented in FIG. 1. However, it is to be understood that the device may assume various alternative orientations, except where expressly specified to the contrary. It is also to be understood that the specific devices and processes illustrated in the attached drawing, and described in the following specification are simply exemplary embodiments of the inventive concepts defined in the appended claims. Hence, specific dimensions and other physical characteristics relating to the embodiments disclosed herein are not to be considered as limiting, unless the claims expressly state otherwise. Additionally, unless otherwise specified, it is to be understood that discussion of a particular feature of a component extending in or along a given direction, or the like, does not mean that the feature or component follows a straight line or axis in such a direction or that it only extends in such direction or on such a plane without other directional components or deviations, unless otherwise specified.

Referring to FIG. 1, an environmental view of an exemplary embodiment of a current detection sensor 10 is shown. The current detection sensor 10 is demonstrated in connection with a remotely operated vehicle 12 (an ROV). As described herein, an ROV may correspond to a variety of vehicles configured to operate in various environments. As demonstrated in FIG. 1, the ROV 12 is shown submerged at a depth D in a liquid (e.g. fresh water, sea water, or various other liquid substances). For clarity, the liquid substance demonstrated in FIG. 1 will be referred to as a liquid 14.

In the exemplary embodiment, the current detection sensor 10 is shown being maneuvered in the liquid 14 by the ROV 12. As will be discussed later in further detail, the current detection sensor 10 may comprise a current probe 16 and a gauge 18. The current detection sensor 10 may be configured to detect electrical current (e.g. direct current) passing through a conductor 20. The conductor 20 may correspond to any form of conductive element configured to transmit an electrical charge. The current probe 16 may comprise a core 22 formed by two mating portions 24. The mating portions 24 may be configured to encircle or enclose about an exterior profile of the conductor 20. In this configuration, the gauge 18 of the current detection sensor 10 may be operable to detect and quantify a magnitude and direction of direct electrical current (DC current) passing through the conductor 20.

As illustrated, the ROV 12 may be configured to maneuver the mating portions 24 to open and close about the conductor 20. The ROV 12 may be in connection with a remote operation controller 26, which may be housed on a vessel 28, a platform 30, and/or a variety of vehicles or facilities suitable to accommodate an operator of the ROV 12. In the exemplary embodiment, the ROV 12 is in connection with the remote operation controller 26 via a control line 32. The control line 32 may be configured to transmit power and various communication signals to the ROV 12 from the remote operation controller 26 and vice versa. In this configuration, an operator of the remote operation controller 26 may control the ROV 12 such that the current probe 16 may be maneuvered to inspect the current passing through the conductor 20.

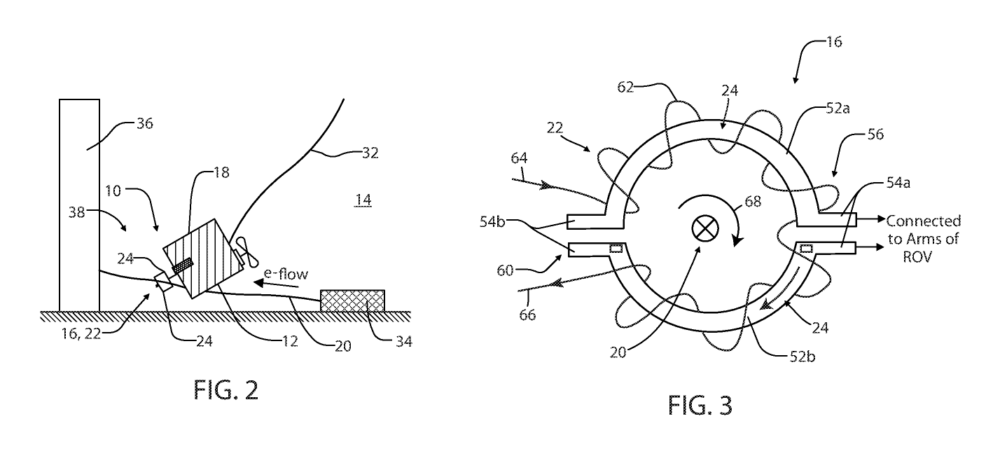

Referring now to FIGS. 1 and 2, the current detection sensor 10 is demonstrated as being applied to inspect the conductor 20. Upon inspection, the current detection sensor 10 may be applied to determine an integrity of the conductor 20 and a magnitude and direction of current passing through the conductor 20. In an exemplary application, the conductor may conductively connect a sacrificial anode 34 to a support structure 36 of the platform 30. Accordingly, the exemplary application of the current detection sensor 10 demonstrated in FIGS. 1 and 2 may correspond to the inspection of a cathodic protection system 38 configured to protect the support structure 36 from corrosion.

In such applications, the ROV 12 and the current detection sensor 10 may be required to be submerged to depths that may exceed 2000 meters below a surface 40 of the liquid 14. Though specifically described in reference to the platform 30 (e.g. a deep sea oil platform), the current detection sensor 10 may be utilized in various applications. For example, such applications may correspond to various underwater applications wherein the current detection sensor including the current probe 16 and the gauge 18 are submerged at the depth D. Other applications may include, but are not limited to, various hostile environments or applications wherein direct interaction in the form of operating and monitoring the results indicated on the gauge 18 may be impossible, dangerous, or inconvenient. Accordingly, the disclosure may provide for various embodiments of the current detection sensor 10 and related detection sensors that may be utilized to measure DC current passing through conductors in a variety of environments.

Referring now to FIG. 3, a schematic diagram of the current probe 16 is shown to demonstrate an exemplary monitoring scenario of the current detection sensor 10. The mating portions 24 of the core 22 are enclosed about the conductor 20. As demonstrated, the current probe 16 may correspond to a clamp on type of non-contact sensor. The core 22 may have a low reluctance and form a plurality of clamp arms 52 forming the mating portions 24 of the core 22. The clamp arms 52a and 52b may comprise a first clamp arm 52a and a second clamp arm 52b each comprising a plurality of lips 54a and 54b. Reluctance is a property similar to electrical resistance, but corresponds to resistance of a material to magnetic inductance. In other words, the lower the reluctance, the easier it is for magnetic flux to flow through the core material. Some examples of materials with low reluctance may include, but are not limited to, iron, iron tape, silicon steel, etc.

The clamp arms 52a and 52b of the core 22 may form a first pair of lips 54a or a similar interface at a proximal end portion 56 of each of the arms 52a and 52b. The first pair of lips 54a may be configured to connect to mechanical actuator arms of the ROV 12. The actuator arms of the ROV 12 may be configured to open and close the first clamp arm 52a and a second clamp arm 52b such that the a distal end portion 60 of the clamp arms 52 can selectively enclose around the conductor 20. Additionally, a second pair of lips 54b may be formed by the core 22 at the distal end portion 60 of each of the arms 52a and 52b. In this configuration, the ROV 12 may be configured to open and close the mating portions 24 in a pinching configuration to enclose about the conductor 20.

A sense winding 62 may be coiled about each of the mating portions 24 of a toroidal shape formed by the core 22. The sense winding 62 may be coupled to the gauge 18 of the current detection sensor 10. In this configuration, the gauge 18 may be configured to emit an input signal to an input 64 of the sense winding 62 and monitor an output 66. The input signal output from the gauge 18 into the input 64 may induce an input field 68 that may influence a magnetic state of the core 22. In this way, the input signal may cause an average current to flow in the sense winding 62. The gauge 18 may then detect the average current as it flows through a sensory resistor to determine an output voltage conducted through the output 66. Based on the output voltage, the gauge 18 may identify the current passing through the conductor 20.

As described herein, the current detection sensor 10 may utilize a variety of methods and hardware configurations to detect current, signals, conductor integrity, or various other properties of conductors and their related systems. Some examples of such methods and hardware configurations are disclosed in the following applications, each of which is incorporated herein by reference in its entirety; U.S. Pat. No. 6,940,267 granted to William H. Swain; U.S. Pat. No. 3,768,011 granted to William H. Swain; U.S. Pat. No. 6,278,952 granted to William H. Swain on the Rgage; and U.S. Pat. No. 6,323,635 of William H. Swain on the MER2.

In operation, the current detection sensor 10 may be controlled by the remote operation controller 26 to practice a method of detecting a performance of a cathodic rust prevention system. The method may begin by connecting the current probe 16 to the ROV 12 and maneuvering the ROV to the conductor 20. The control instructions for maneuvering the ROV may be communicated from the remote operation controller 26 via the control line 32. The remote operation controller 26 may continue controlling the ROV 12 connecting the current probe 16 around the conductor 20. Once connected, the remote operation controller 26 may communicate a control instruction to an ROV controller of the ROV causing the ROV controller to activate a gauge 18 of the current detection sensor 10 to activate a current detection routine of the current probe 16. Once activated, the gauge 18 may detect and record electrical properties of current transmitted through the conductive wire with the current probe 16. In this way, the current detection sensor 10 may be operable to detect a performance of the sacrificial anode 34 connected to the conductor 20 by measuring the current transmitted through the conductor 20.

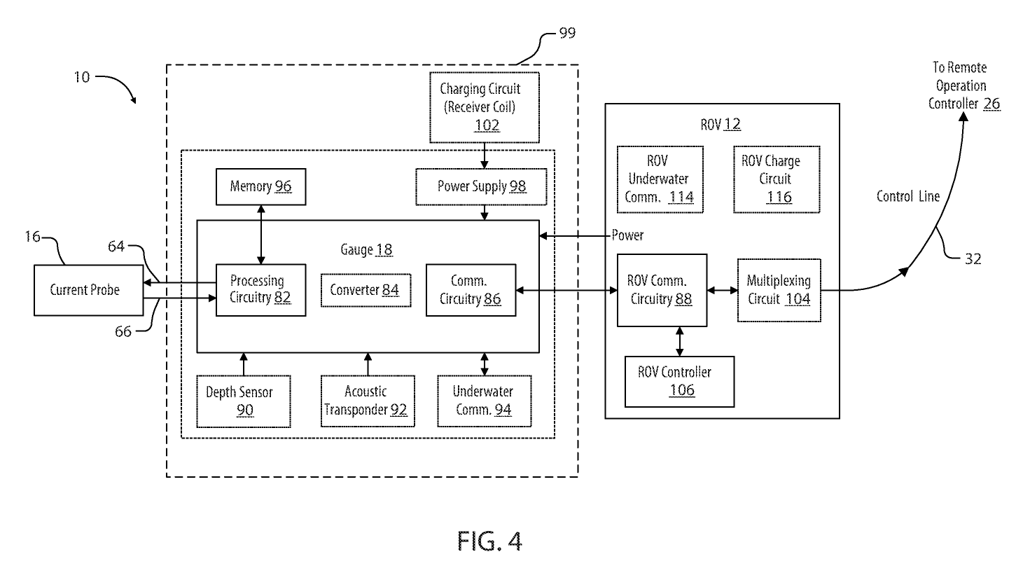

Referring now to FIG. 4, a block diagram of the current detection sensor 10 in communication with the ROV 12 is shown. As discussed herein, in an exemplary embodiment, the current detection sensor 10 may be configured to process an output signal received via the output 66 of the current probe 16. The output signal may be received via an analog input of a processing circuitry 82 of the gauge 18. The processing circuitry 82 may correspond to one or more analog or digital circuits configured to receive and interpret the current signal at the output 66 of the sense winding 62. The processing circuitry 82 may be in communication with a converter 84, which may be configured to convert an analog signal from the processing circuitry 82 to a digital signal or vice versa. Accordingly, the gauge 18 may be optimized to suit a variety of configurations in accordance with the disclosure.

The gauge 18 may further comprise one or more communication circuits 86 which may be in communication with the processing circuitry 82 and/or the converter 84. The communication circuit 86 may correspond to various forms of communication protocols. For example, communication protocols may correspond to process automation protocols, industrial system protocols, vehicle protocol busses, consumer communication protocols, etc. In an exemplary embodiment, the communication circuit 86 may be configured to communicate with the ROV 12 via a serial communication protocol (e.g. RS-422/485). Additional protocols may include, MODBUS, PROFIBUS, CAN_bus, DATA HIGHWAY, DEVICENET, or various forms of communication standards. In this configuration, signal information identifying the magnitude, direction, and various other properties of the current flowing through the conductor 20 may be communicated from the communication circuit 86 of the current detection sensor 10 to an ROV communication circuit 88.

In various embodiments, the gauge 18 may comprise a variety of additional circuits, peripheral devices, and/or accessories, which may be incorporated into the gauge 18 to provide various functions. For example, in some embodiments, the gauge 18 may comprise a depth sensor 90, an acoustic transponder 92, an underwater communications transponder 94, a memory 96, and/or a power supply 98. Additionally, each of the devices or accessories in communication with or forming an integral portion of the gauge 18 may be disposed in a watertight housing 99, which may be configured to protect the gauge 18 from impact that may occur in various environments and/or water or pressure damage related to operation when submerged in the liquid 14. The watertight housing 99 may be formed of various watertight, rigid materials, such as metals, polymers, etc.

The depth sensor 90 may correspond to a pressure sensor. The pressure sensor may correspond to any suitable form of sensor including, but not limiting to, a silicon diaphragm wet transducer, a strain gauge pressure sensor, and various sensors which may vary based on a desired performance and monitoring application. The gauge 18 may further comprise an acoustic transponder 92. The acoustic transponder 92 may be configured to communicate with a hull-mounted transducer of the vessel 28 such that a relative distance and orientation of the current detection sensor 10 may be inferred from communication signals.

For example, the hull-mounted transducer may send and receive signals to and from the acoustic transponder 92 and identify a relative approach angle of signals received by the acoustic transponder 92 to identify the location of the current detection sensor 10. Such information may be communicated to the gauge 18 via the ROV 12 such that the gauge 18 may record the location of the current detection sensor 10 in the memory 96 in reference to the current measurements received from the current probe 16. In this configuration, the current detection sensor 10 may provide for the monitoring and measurement of current passing through the conductor 20, which may be processed by the processing circuitry 82 and stored in the memory 96. In some embodiments, results of the monitoring and/or measurements may be stored in the memory 96 in combination with location data derived from the interaction of the acoustic transponder 92 with the hull-mounted transducer. Though referred to specifically as a hull-mounted transducer, the transducer operating in combination with the acoustic transponder 92 may correspond to any suitable type of transducer which may be mounted on the platform 30 or various other structures or vehicles.

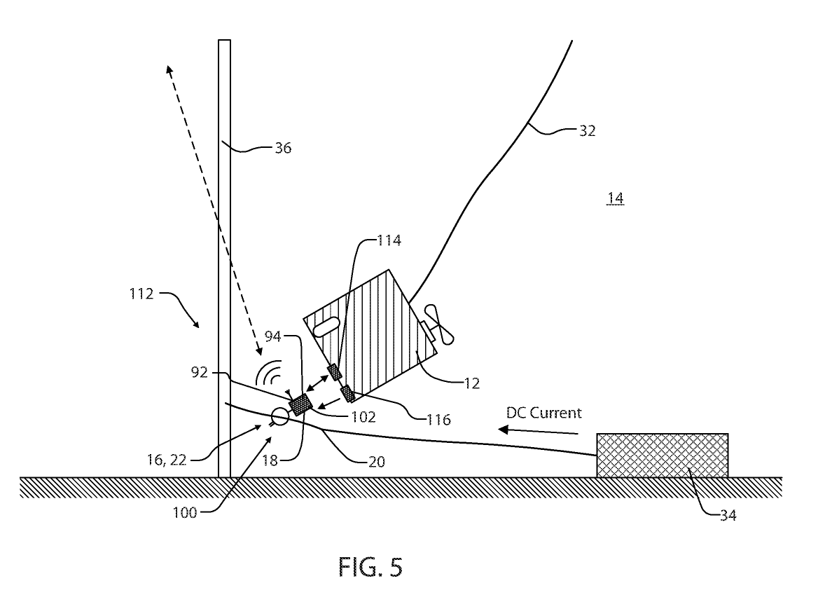

The underwater communications transponder 94 may correspond to an acoustic modem configured to communicate underwater with similarly equipped or compatible acoustic communication systems. The power supply 98 may correspond to various forms of batteries, some of which may be rechargeable to provide for extended use of the current detection sensor 10. In an exemplary embodiment, the power supply 98 may be coupled to a charging circuit 102. The charging circuit 102 may correspond to an inductive charging circuit comprising a receiver coil which may be housed within the watertight housing 99. In this configuration, the power supply 98 may be wirelessly charged via a charging station without disturbing the circuitry of the gauge 18. Charging the power supply 98 without distributing or jeopardizing the integrity of gauge 18 may be beneficial because various components of the gauge 18 may be sensitive to conditions existing outside the watertight housing 99. Further details regarding an exemplary embodiment of the current detection sensor 10 that further describes the operation in reference to the charging circuit 102 and the underwater communications transponder 94 are further discussed in reference to FIG. 5.

In some embodiments, the current detection sensor 10 may comprise the communication circuitry 86 in communication with the ROV communication circuit 88. In such embodiments, the current detection sensor 10 may receive operating power from the ROV 12. This configuration may take advantage of power that may be supplied to the ROV 12 via the control line 32. The ROV 12 may receive operating instructions via a multiplexing circuit 104 which may further be in communication with the ROV communication circuit 88. In this way, the remote operation controller 26 may communicate instructions to the multiplexing circuit 104 and an ROV controller 106 via the ROV communication circuit 88.

As such, the ROV 12 may receive operational instructions from the remote operation controller 26 via the control line 32. The control line 32 may correspond to various forms of communication lines, and may correspond to a digital communication line or fiber optic communication line. The control line 32 may be reinforced and specifically designed to sustain communications between the remote operation controller 26, the ROV 12, and the current detection sensor 10 when the current detection sensor 10 is operated at high depths of the liquid 14 or various other extreme conditions.

The ROV controller 106 may communicate and provide control instructions to gauge 18 via the ROV communication circuit 88. For example, the ROV controller 106 may receive a command via the control line 32 configured to cause the activation of the current probe 16 of the gauge 18. In response to receiving the instruction from the control line 32, the ROV controller 106 may communicate an activation instruction to the gauge 18. In response to receiving the activation instruction from the ROV communication circuit 88, the gauge 18 may activate the input signal at the input 64 at the current probe 16. The gauge 18 may also monitor the output 66 of the current probe 16 to identify the current or other electrical properties of a conductor 20 enclosed within the mating portions 24 of the current probe 16. The current or various other electrical properties identified in relation to the conductor 20 may be referred to herein after as results for clarity.

Upon capturing the results, the processing circuitry 82 of the gauge 18 may store the results in the memory 96 or communicate the results to the ROV communication circuit 88. In this way, the results may be stored in the memory 96 for later retrieval or communicated back to the remote operation controller 26 via the multiplexing circuit 104 and the control line 32. As described herein, the disclosure provides for an integrated system in which the current detection sensor 10 may be utilized in combination with the ROV 12 to achieve seamless operation with expedient feedback via control line 32. In this way, the current detection sensor 10 may provide for improved accuracy and convenience in the inspection of the conductor 20.

As discussed herein, the remotely operated vehicle (see ROV) 12 may correspond to various forms of remotely operated or autonomous vehicles configured to operate in hazardous or extreme environments. Such vehicles may be optimized to suit various desired applications of the current detection sensor 10 as described herein. Accordingly, the disclosure may provide for various embodiments of flexible monitoring or detection systems that may be utilized to monitor direct current passing through conductive materials.

FIG. 5 demonstrates an environmental view of the current detection sensor 100. Referring now to FIGS. 4 and 5, the current detection sensor 100 may be similar to the current detection sensor 10 having like elements numbered the same. Focusing on the differing aspects of the current detection sensor 100, wherein the current detection sensor 10 was discussed as being configured to operate in connection with the ROV 12, the current detection sensor 100 may be configured to be positioned in a remote location 112 for an extended period of time. Accordingly, the current detection sensor 100 may comprise various properties or utilities configured to enable such operation.

In some embodiments, the current detection sensor 100 may comprise the acoustic transponder 92. In this way, a nearby vessel 28 or the platform 30 may be operable to detect a location of the current detection sensor 100. Determining a location of the current detection sensor 100 may be especially beneficial when attempting to retrieve or locate the current detection sensor 100 for service. As demonstrated in FIG. 5, the ROV 12 is demonstrated in close proximity to the current detection sensor 100 and submerged in the liquid 14. The current probe 16 of the current detection sensor 10 is shown enclosed about the conductor 20.

In this example, the current detection sensor 10 may have recorded results or current data identifying the electrical current passing through the conductor 20 over an extended period of time. In such applications, the processing circuitry 82 may process the results and store them in the memory 96. In order to retrieve the results from the gauge 18, the ROV 12 may comprise a wireless communication circuit 114 configured to wirelessly communicate with the underwater communications transponder 94 of the gauge 18. The underwater communication transponder 94 and the wireless communication circuit 114 may be operable to communicate the results of the current data via a number of wireless communication protocols. For example, the underwater communication transponder 94 and the wireless communication circuit 114 may communicate via underwater optical wireless communication (UOWC) or underwater acoustic communication systems. In this way, the current detection sensor 100 may be configured to record the results over an extended period of time and communicate the results to the ROV 12 without requiring that the current detection sensor 100 be removed from the remote location 112.

In an exemplary embodiment, the current detection sensor 100 may comprise the charging circuit 102. Similar to the underwater communication transponder 94, the charging circuit 102 may provide for wireless interaction with the current detection sensor 100. Accordingly, the charging circuit 102 may be configured to replenish the power supply 98 of the current detection sensor 100 wirelessly and without breaching the housing 99. As described herein, the current detection sensor 100 may provide for sustained operation over long periods of time without disturbing the watertight housing 99.

The charging circuit 102 of the current detection sensor 10 may correspond to a resonant inductive power coupling configured to operate under water. For example, the charging circuit 102 may comprise a receiver coil in the form of a two coil or four coil highly resonant inductive coil. In this configuration, the current detection sensor 100 may be configured to receive power wirelessly from the ROV charging circuit 116 such that the power supply 98 may be recharged without repositioning the current detection sensor 100. As such, the current detection sensor 100 may be utilized in a variety of applications in combination with or independently from the ROV 12.

It is to be understood that variations and modifications can be made on the aforementioned structure without departing from the concepts of the present disclosure, and further it is to be understood that such concepts are intended to be covered by the following claims unless these claims by their language expressly state otherwise.

For purposes of this disclosure, the term “coupled” (in all of its forms, couple, coupling, coupled, etc.) generally means the joining of two components (electrical or mechanical) directly or indirectly to one another. Such joining may be stationary in nature or movable in nature. Such joining may be achieved with the two components (electrical or mechanical) and any additional intermediate members being integrally formed as a single unitary body with one another or with the two components. Such joining may be permanent in nature or may be removable or releasable in nature unless otherwise stated.

It is also important to note that the construction and arrangement of the elements of the disclosure as shown in the exemplary embodiments is illustrative only. Although only a few embodiments of the present innovations have been described in detail in this disclosure, those skilled in the art who review this disclosure will readily appreciate that many modifications are possible (e.g., variations in sizes, dimensions, structures, shapes and proportions of the various elements, values of parameters, mounting arrangements, use of materials, colors, orientations, etc.) without materially departing from the novel teachings and advantages of the subject matter recited. For example, elements shown as integrally formed may be constructed of multiple parts or elements shown as multiple parts may be integrally formed, the operation of the interfaces may be reversed or otherwise varied, the length or width of the structures and/or members or connector or other elements of the system may be varied, the nature or number of adjustment positions provided between the elements may be varied. It should be noted that the elements and/or assemblies of the system may be constructed from any of a wide variety of materials that provide sufficient strength or durability, in any of a wide variety of colors, textures, and combinations. Accordingly, all such modifications are intended to be included within the scope of the present innovations. Other substitutions, modifications, changes, and omissions may be made in the design, operating conditions, and arrangement of the desired and other exemplary embodiments without departing from the spirit of the present innovations.

It will be understood that any described processes or steps within described processes may be combined with other disclosed processes or steps to form structures within the scope of the present disclosure. The exemplary structures and processes disclosed herein are for illustrative purposes and are not to be construed as limiting.

What is claimed is:

1. A current detection sensor comprising:
a current probe configured to connect to a remotely operated vehicle (ROV), the current probe comprising a low reluctance core configured to selectively enclose about a conductor in response to an actuation of the ROV; and
a gauge comprising a gauge controller in conductive communication with an input and an output of the current probe, wherein the gauge controller is configured to identify transmission data for the conductor based on a detection routine comprising:
supplying an input signal to the input;
monitoring a voltage at the output; and
identifying electrical properties of current transmitted through the conductor based on the voltage.

2. The current detection sensor according to claim 1, wherein the current probe comprises a first clamp arm and a second clamp arm configured to enclose around the conductor and connect to an actuation device of the ROV.

3. The current detection sensor according to claim 1, wherein the gauge controller is in communication with an ROV controller of the ROV, wherein the gauge controller is configured to receive control instructions from the ROV controller and execute the detection routine in response to the control instructions.

4. The current detection sensor according to claim 3, wherein the gauge controller communicates the transmission data to the ROV controller.

5. The current detection sensor according to claim 4, wherein the ROV controller is in communication with a remote operation controller via a control line.

6. The current detection sensor according to claim 5, wherein the ROV controller is configured to communicate the control instructions to the gauge controller in response to remote instructions received from the remote operation controller via the control line.

7. The current detection sensor according to claim 5, wherein the ROV controller is configured to maneuver the ROV in response to the control instructions received via the control line.

8. A method for detecting a performance of a cathodic rust prevention system with a current detection sensor, the method comprising:
connecting a current probe to a remotely operated vehicle (ROV);
maneuvering the ROV;
controlling the ROV connecting the current probe around a conductive wire;
communicating a control instruction to an ROV controller of the ROV;
activating with the ROV controller a current detection routine of the probe; and
detecting electrical properties of current transmitted through the conductive wire with the current probe.

9. The method according to claim 8, wherein the connecting the current probe around the conductive wire comprises actuating a pair of clamp arms of the current probe enclosing the clamp arms around the conductive wire with the ROV.

10. The method according to claim 8, wherein the ROV is configured to operate submerged in a liquid substance and the maneuvering of the ROV is through the liquid substance.

11. The method according to claim 10, wherein the maneuvering the ROV comprises receiving maneuvering instructions from a remote operation controller via a communication line.

12. The method according to claim 11, further comprising:
extending the communication line into the liquid substance thereby connecting the remote operation controller to the ROV.

13. The method according to claim 12, further comprising communicating the electrical properties of the current transmitted through the conductive wire to the remote operation controller via ROV controller and the communication line.

14. The method according to claim 8, further comprising detecting the performance of a sacrificial anode connected to the conductive wire by measuring the current transmitted through the conductive wire.

15. The method according to claim 14, further comprising communicating the performance of the sacrificial anode to a remote operation controller providing for remote inspection of the sacrificial anode through a liquid substance.

16. A current detection sensor for underwater use comprising:
a current probe comprising a low reluctance core forming a plurality of clamp arms configured to selectively enclose about a conductor;
a gauge comprising a gauge controller enclosed in a watertight housing;
a battery housed within the watertight housing, wherein the gauge controller is in conductive communication with an input and an output of the current probe, wherein the gauge controller is configured to identify current transmission data for current communicated through the conductor with a detection routine, and wherein the gauge controller is configured to control the detection routine of the current probe comprising:
supplying an input signal to the input;
monitoring a voltage at the output; and
identifying electrical properties of current transmitted through the conductor based on the voltage.

17. The current detection sensor according to claim 16, further comprising:
a wireless communication circuit disposed in the gauge configured to communicate the current transmission data results from the current probe.

18. The current detection sensor according to claim 17, wherein the wireless communication circuit is configured to wirelessly communicate the current transmission data through a liquid substance in which the current detection sensor is submerged.

19. The current detection sensor according to claim 16, wherein the gauge further comprises:
a wireless charging circuit in connection with the battery of the gauge.

20. The current detection sensor according to claim 19, wherein the charging circuit is an inductive charging circuit configured to wirelessly replenish a charge of the battery.
